(19) United States
(12) Patent Application Publication
(10) Pub. No.: US 2024/0395540 A1
(43) Pub. Date: Nov. 28, 2024

(54) Microelectromechanical Systems (MEMS) Fabrication Process Including Atomic Layer Deposition (ALD) Of Conformal Coatings For Hermetic Encapsulation

(71) Applicant: StethX Microsystems, Atlanta, GA (US)

(72) Inventors: Farrokh Ayazi, Atlanta, GA (US); Haoran Wen, Atlanta, GA (US)

(21) Appl. No.: 18/676,060

(22) Filed: May 28, 2024

Related U.S. Application Data
(60) Provisional application No. 63/504,690, filed on May 26, 2023.

(51) Int. Cl. H01L 21/02; H01L 21/311; H01L 21/56; H01L 21/762; H01L 21/78

(52) U.S. Cl. CPC H01L 21/02178; H01L 21/0228; H01L 21/31122; H01L 21/561; H01L 21/76251; H01L 21/78

(57) ABSTRACT

Devices, fabrication processes, and methods for hermetic encapsulation of micro-electromechanical system (MEMS) devices. The method comprises depositing a first conformal alumina layer to coat at least a portion of the MEMS device. The first conformal alumina layer is configured to coat one or more exposed surfaces of the MEMS device. The method also comprises removing at least a portion of a deposited first conformal alumina layer from one or more impermeable surfaces of the MEMS device.

### CROSS-REFERENCE TO RELATED APPLICATIONS

This application claims the priority benefit of U.S. Provisional Patent Application Ser. No. 63/504,690, filed May 26, 2023, which is hereby incorporated by reference in its entirety.

### BACKGROUND OF THE DISCLOSURE

### 1. Field of the Invention

The present invention relates to the field of microelectromechanical systems (MEMS), and more particularly to encapsulation methods for MEMS devices for operation stability, performance consistency, and robustness against environmental variations.

### 2. Description of Related Art

“MEMS” generally refers to apparatus incorporating some mechanical structure having a dimensional scale that is comparable to microelectronic devices. For example, less than approximately 250 μm. This mechanical structure is typically capable of some form of mechanical motion and is formed at the micro-scale using fabrication techniques like those utilized in the microelectronic industry such as thin film deposition, and thin film patterning by photolithography and reactive ion etching (RIE). The micromechanical structure in a MEMS device distinguishes a MEMS device from a microelectronic device.

Some designs of MEMS require hermetic encapsulation in order for the MEMS device to have performance consistency and be robust against environmental variations. For example, some designs of MEMS accelerometers require certain controlled cavity pressure to maintain desired operation bandwidth. Other examples include MEMS based accelerometers, gyroscopes and resonators usually require hermetic packaging in a vacuum cavity for reduced air damping and high Q-factor. Hermetic encapsulation of MEMS devices is designed to prevent small gas molecules from permeating through certain materials of the MEMS, such as silicon dioxide, as to not affect the operational stability, performance consistency, and robustness against environmental variations of the MEMS devices. Silicon dioxide, commonly used in MEMS devices, is known to be permeable to small gas molecules. As such, MEMS devices fabricated and packaged using substrates that include silicon-dioxide layers, such as a silicon-on-insulation (SOI) wafer, are not hermetic against helium and hydrogen ingression. This places a significant limit on MEMS device usage in applications involving helium (or hydrogen) exposure, such as implantable medical devices.

Thus, technological innovation is needed to provide methods and fabrication processes for hermetic encapsulation of MEMS devices that overcome the limitations of the conventional systems, methods, and fabrication processes. Thus, one focus of the present invention is to provide methods and fabrication processes related thereof that hermetically encapsulates MEMS devices.

### BRIEF SUMMARY OF THE INVENTION

Briefly described, according to exemplary embodiments of the present invention, devices, systems, and method of an innovative system comprising a radiation detection device. In some exemplary embodiments, the present invention comprises at least one tunnel oxide layer configured to be a passivating contact.

In an exemplary embodiment of the present invention, a method may be configured for hermetic encapsulation of a micro-electromechanical system (MEMS) device. The method may comprise depositing a first conformal alumina layer to coat at least a portion of the MEMS device. The first conformal alumina layer is configured to coat one or more exposed surfaces of the MEMS device. The method may further comprise removing at least a portion of a deposited first conformal alumina layer from one or more impermeable surfaces of the MEMS device.

In various embodiments, the method may further comprise depositing one or more additional conformal alumina layers to coat at least a portion of one or more exposed surfaces disposed along a bottom portion of the MEMS device. The deposition of the first conformal alumina layer and the one or more additional conformal layers may utilize an atomic layer deposition (ALD) method. In various embodiments, the one or more exposed surfaces at least partially coated by a respective conformal alumina layer may be configured to be permeable to hydrogen, helium, or a combination thereof. In an example embodiment, the first conformal alumina layer and/or the one or more additional conformal alumina layer may be configured to coat one or more exposed surfaces of an undercut region, an interconnection, a capping layer, or a combination thereof.

In one or more embodiments, the removing of at least a portion of the first deposited conformal alumina layer from the one or more impermeable surfaces may utilize one or more of the following processes: blanket etching, reactive-ion etching, focused ion beam etching, laser trimming, or a combination thereof.

In another exemplary embodiment of the present invention, a method is provided for hermetic encapsulation of a micro-electromechanical system (MEMS) device. The method may comprise removing one or more passivation surfaces of an interconnection portion of the MEMS device along at least one dicing lane. The one or more passivation surfaces may be permeable. The method may further comprise depositing a first conformal alumina layer to coat at least a portion of the interconnection portion. The first conformal alumina layer may coat at least a portion of the one or more exposed surfaces. The method may further comprise dicing at least a portion of a bonded wafer. The method may also comprise depositing one or more additional conformal alumina layer to coat at least a portion of the bonded wafer. The one or more additional conformal alumina layer may coat at least a portion of one or more exposed surfaces.

In various embodiments, the method may further comprise bonding the interconnection portion to a device portion to form the bonded wafer. The device portion may contain one or more electrical components for the MEMS device. In one or more embodiments, the method may further comprise removing at least a portion of the deposited first conformal alumina layer and/or the deposited one or more additional conformal alumina layers from one or more impermeable surfaces of the MEMS device. In an example embodiment, the deposition of the first conformal alumina layer and the one or more additional conformal layers may utilize an atomic layer deposition (ALD) method.

In one or more embodiments, one or more exposed surfaces coated by a respective conformal alumina layer may be permeable to hydrogen, helium, or a combination thereof. In various embodiments, the first conformal alumina layer and/or the one or more additional conformal alumina layer may coat one or more exposed surfaces of an undercut region, an interconnection, a capping layer, or a combination thereof. In various embodiments, the removal of at least a portion of the first deposited conformal alumina layer and/or the deposited one or more additional conformal alumina layers from the one or more impermeable may be done by one or more of the following processes: blanket etching, reactive-ion etching, focused ion beam etching, laser trimming, or a combination thereof.

In yet another exemplary embodiment of the present invention, a fabrication process is provided for hermetic encapsulation of a micro-electromechanical system (MEMS) device. The fabrication process may include removing one or more passivation layers from one or more dicing lanes on an interconnection portion and/or a device portion of a MEMS device. The removing of the one or more passivation layer may expose one or more surfaces of the MEMS device. The fabrication process may further include depositing a first conformal alumina layer to coat at least a portion of the interconnection portion and/or device portion, wherein the first conformal alumina layer coats at least a portion of the one or more exposed surfaces. The fabrication process may also include dicing at least a portion of the interconnection portion and/or device portion.

In various embodiments, the fabrication process may further include bonding the interconnection portion to the device portion to form the bonded wafer. The device portion may be configured to contain one or more electrical component for the MEMS device. In various embodiments, the fabrication process may further include depositing a one or more additional conformal alumina layer to coat at least a portion of the bonded wafer. The one or more additional conformal alumina layer may coat at least a portion of one or more exposed surfaces. In an example embodiment, the fabrication process may also include removing at least a portion of the deposited first conformal alumina layer and/or the deposited one or more additional conformal alumina layers from one or more impermeable surfaces of the MEMS device. In various embodiments, the one or more exposed surfaces coated by a respective conformal alumina layer may be permeable to hydrogen, helium, or a combination thereof.

In various embodiments, the first conformal alumina layer and the one or more additional conformal layer may coat one or more exposed surfaces of an undercut region, an interconnection, a capping layer, or a combination thereof. In one or more embodiments, the removal of at least a portion of the first deposited conformal alumina layer and/or the one or more additional deposited conformal alumina layer from the one or more impermeable surfaces may utilize one or more of the following processes: blanket etching, reactive-ion etching, focused ion beam etching, laser trimming, or a combination thereof.

In yet another exemplary embodiment of the present invention, a micro-electromechanical system (MEMS) device that may comprise a device portion. The MEMS device may further comprise at least one interconnection portion. The MEMS device may further comprise at least one capping portion. The MEMS device may also comprise at least one hermetic encapsulation layer. The at least one hermetic encapsulation layer may cover at least a portion of the device portion, at least one interconnection portion, at least one capping portion, and/or bonded wafer. The at least one hermetic encapsulation may be formed by a fabrication process. The fabrication process may include removing at least a portion of one or more passivation layers from one or more dicing lanes on an interconnection portion and/or a device portion of a MEMS device. The removal of the portion of one or more passivation layer exposes one or more surfaces of the MEMS device. The fabrication process may also include depositing a first conformal alumina layer to coat at least a portion of the at least one interconnection portion, device portion, at least one capping portion, and/or bonded wafer, wherein the first conformal alumina layer coats at least a portion of the one or more exposed surfaces.

In various embodiments, the fabrication process of the at least one encapsulation layer may also include dicing at least a portion of the interconnection portion and/or device portion. In various embodiments, the fabrication process of the at least one encapsulation layer may further include bonding the at least one interconnection portion to the device portion to form the bonded wafer. The device portion may be configured to contain one or more electrical component for the MEMS device. In one or more embodiments, the fabrication process of the at least one encapsulation layer may further include depositing one or more additional conformal alumina layer to coat at least a portion of the bonded wafer, wherein the one or more additional conformal alumina layer coats at least a portion of one or more exposed surfaces.

In various embodiments, the fabrication process of the at least one encapsulation layer may further include removing at least a portion of the deposited first conformal alumina layer and/or the deposited one or more additional conformal alumina layers from one or more impermeable surfaces of the MEMS device. In various embodiments, one or more exposed surfaces coated by a respective conformal alumina layer are permeable to hydrogen, helium, or a combination thereof. In various embodiments, the first conformal alumina layer and the one or more additional conformal layer may coat one or more exposed surfaces of an undercut region of at least one interconnection portion, at least one capping portion, device portion, bonded wafer, or a combination thereof.

In various embodiments, removing at least a portion of the first deposited conformal alumina layer and/or the one or more additional deposited conformal alumina layer from the one or more impermeable surfaces may utilize one or more of the following processes: etching, blanket etching, reactive-ion etching, focused ion beam etching, laser trimming, or a combination thereof. In one or more embodiments, the deposition of the first conformal alumina layer and the one or more additional conformal layers may utilize an atomic layer deposition (ALD) method. In various embodiments, the at least one capping portion and/or device portion may be configured to at least partially house one or more electronic component, device, system, or combination thereof. In various embodiments, at least a portion of the device portion, at least one interconnection portion, at least one capping portion, and/or bonded wafer may comprise permeable material. In various embodiments, the permeable material may be permeable to hydrogen, helium, or a combination thereof.

In various embodiments, a micro-electromechanical system (MEMS) device may comprise at least one conformal alumina layer coating at least a portion of the MEMS device. In various embodiments, a micro-electromechanical system (MEMS) device may further comprise at least one impermeable surface not coated by the at least one conformal alumina layer. In various embodiments, a micro-electromechanical system (MEMS) device may further comprise a device portion, at least one interconnection portion, and at least one capping portion, wherein the at least one conformal alumina layer coats at least a portion of at least one of the device portion, the at least one interconnection portion, and the at least one capping portion. In one or more embodiments, the at least one conformal alumina layer may hermetically seal at least a portion of the MEMS device. In various embodiments, the portion of the MEMS device coated by the at least one conformal alumina layer may be permeable to hydrogen, helium, or a combination thereof.

These and other objects, features, and advantages of the present invention will become more apparent upon reading the following specification in conjunction with the accompanying drawings.

### BRIEF DESCRIPTION OF THE DRAWINGS

Implementations, features, and aspects of the disclosed technology are described in detail herein and are considered a part of the claimed disclosed technology. Other implementations, features, and aspects can be understood with reference to the following detailed description, accompanying drawings, and claims. Wherever possible, the same reference numbers are used throughout the drawings to refer to the same or like members of an embodiment. Reference will now be made to the accompanying figures and flow diagrams, which are not necessarily drawn to scale.

FIG. 1A illustrates an exemplary schematic cross-sectional view of a MEMS device with a conformal alumina layer according to various embodiments of the present disclosure.

FIG. 1B illustrates an exemplary schematic cross-sectional view of a portion of a MEMS device with a conformal alumina layer according to various embodiments of the present disclosure.

FIG. 2A illustrates an exemplary schematic view of a MEMS device according to various embodiments of the present disclosure.

FIG. 2B illustrates a conformal alumina layer coating at least a portion of a MEMS device according to various embodiments of the present disclosure.

FIG. 2C illustrates removal of a conformal alumina layer coating from at least a portion of a MEMS device according to various embodiments of the present disclosure.

FIG. 3 illustrates exemplary MEMS devices according to various embodiments of the present disclosure.

FIG. 4A illustrates a flow diagram of an exemplary wafer-level method and fabrication process with reference to FIGS. 4B-4G according to various embodiments of the present disclosure.

FIG. 4B illustrates a portion of an exemplary method and fabrication process, showing passivation layer removal, according to various embodiments of the present disclosure.

FIG. 4C illustrates a portion of an exemplary method and fabrication process, showing wafer bonding, according to various embodiments of the present disclosure.

FIG. 4D illustrates a portion of an exemplary method and fabrication process, showing partial dicing, according to various embodiments of the present disclosure.

FIG. 4E illustrates a portion of an exemplary method and fabrication process, showing conformal alumina layer deposition, according to various embodiments of the present disclosure.

FIG. 4F illustrates a portion of an exemplary method and fabrication process, showing pattering of a conformal alumina layer, according to various embodiments of the present disclosure.

FIG. 4G illustrates a portion of an exemplary method and fabrication process, showing dicing of a bonded wafer and singulation of a MEMS device, according to various embodiments of the present disclosure.

FIG. 5A illustrates a flow diagram of an exemplary wafer-level method and fabrication process with reference to FIGS. 5B-5I according to various embodiments of the present disclosure.

FIG. 5B illustrates a portion of an exemplary method and fabrication process, showing passivation layer removal and conformal alumina coating, according to various embodiments of the present disclosure.

FIG. 5C illustrates a portion of an exemplary method and fabrication process, showing patterning of a conformal alumina layer, according to various embodiments of the present disclosure.

FIG. 5D illustrates a portion of an exemplary method and fabrication process, showing bond metal deposition, according to various embodiments of the present disclosure.

FIG. 5E illustrates a portion of an exemplary method and fabrication process, showing wafer bonding, according to various embodiments of the present disclosure.

FIG. 5F illustrates a portion of an exemplary method and fabrication process, showing partial dicing, according to various embodiments of the present disclosure.

FIG. 5G illustrates a portion of an exemplary method and fabrication process, showing an additional conformal alumina layer deposition, according to various embodiments of the present disclosure.

FIG. 5H illustrates a portion of an exemplary method and fabrication process, showing etching of one or more surfaces, according to various embodiments of the present disclosure.

FIG. 5I illustrates a portion of an exemplary method and fabrication process, showing a completed wafer, according to various embodiments of the present disclosure.

FIG. 6 illustrates a flow diagram of an exemplary chip-level method and fabrication process according to various embodiments of the present disclosure.

### DETAIL DESCRIPTION OF THE INVENTION

Although certain embodiments of the disclosure are explained in detail, it is to be understood that other embodiments are contemplated. Accordingly, it is not intended that the disclosure is limited in its scope to the details of the construction and arrangement of components set forth in the following description or illustrated in the drawings. Other embodiments of the disclosure are capable of being practiced or carried out in various ways. Also, in describing the embodiments, specific terminology will be resorted to for the sake of clarity. It is intended that each term contemplates its broadest meaning as understood by those skilled in the art and includes all technical equivalents which operate in a similar manner to accomplish a similar purpose.

It should also be noted that, as used in the specification and the appended claims, the singular forms “a,” “an,” and “the” include plural references unless the context clearly dictates otherwise. References to a composition containing “a” constituent is intended to include other constituents in addition to the one named.

Ranges may be expressed herein as from “about” or “approximately” or “substantially” one particular value and/or to “about” or “approximately” or “substantially” another particular value. When such a range is expressed, other exemplary embodiments include from the one particular value and/or to the other particular value.

Herein, the use of terms such as “having,” “has,” “including,” or “includes” are open-ended and are intended to have the same meaning as terms such as “comprising” or “comprises” and not preclude the presence of other structure, material, or acts. Similarly, though the use of terms such as “can” or “may” are intended to be open-ended and to reflect that structure, material, or acts are not necessary, the failure to use such terms is not intended to reflect that structure, material, or acts are essential. To the extent that structure, material, or acts are presently considered to be essential, they are identified as such.

Similarly, as used herein, “substantially free” of something, or “substantially pure”, and like characterizations, can include both being “at least substantially free” of something, or “at least substantially pure”, and being “completely free” of something, or “completely pure”.

As used herein, unless otherwise specified the use of the ordinal adjectives “first,” “second,” “third,” etc., to describe a common object, merely indicate that different instances of like objects are being referred to, and are not intended to imply that the objects so described must be in a given sequence, either temporally, spatially, in ranking, or in any other manner. By “comprising” or “containing” or “including” is meant that at least the named element, or method step is present in article or method, but does not exclude the presence of other elements or method steps, even if the other such elements or method steps have the same function as what is named.

Mention of one or more method steps does not preclude the presence of additional method steps or intervening method steps between those steps expressly identified. Similarly, it is also to be understood that the mention of one or more components in a device, method, or fabrication process does not preclude the presence of additional components or intervening components between those components expressly identified.

The materials described as making up the various elements of the invention are intended to be illustrative and not restrictive. Many suitable materials that would perform the same or a similar function as the materials described herein are intended to be embraced within the scope of the invention. Such other materials not described herein can include, but are not limited to, for example, materials that are developed after the time of the development of the invention.

The components described hereinafter as making up various elements of the disclosure are intended to be illustrative and not restrictive. Many suitable components that would perform the same or similar functions as the components described herein are intended to be embraced within the scope of the disclosure. Such other components not described herein can include, but are not limited to, for example, similar components that are developed after development of the presently disclosed subject matter. Additionally, the components described herein may apply to any other component within the disclosure. Merely discussing a feature or component in relation to one embodiment does not preclude the feature or component from being used or associated with another embodiment.

To facilitate an understanding of the principles and features of the disclosure, various illustrative embodiments are explained below. In particular, the presently disclosed subject matter is described in the context of microelectromechanical systems (MEMS) devices and, in particular, hermetic encapsulation of one or more MEMS devices to prevent permutation of small gas molecules (e.g., helium, hydrogen, etc.). The present disclosure, however, is not so limited and can be applied in other concepts. For example, some examples of the present disclosure may improve the manufacturing process of other microelectromechanical systems.

In various embodiments of the present disclosure, a method and/or fabrication process for hermetic encapsulation may be performed at a chip-level and/or a wafer-level. In one or more embodiments, the methods and/or fabrication processes of one or more MEMS devices can include depositing at least one conformal alumina layer. The at least one conformal alumina layer may coat at least a portion of the one or more MEMS devices. Additionally and/or alternatively, the at least one conformal alumina layer may coat one or more exposed surfaces of the one or more MEMS devices. The one or more exposed surfaces may be permeable to small gas molecules, non-permeable to small gas molecules, or a combination thereof. In some examples, the methods and/or fabrication processes may further include removing at least a portion of the at least one deposited conformal alumina layer. The removal of at least a portion of the at least one deposited conformal alumina layer may be at one or more locations, such that the one or more locations comprise an impermeable material, such as the electrical connection metal pads.

The present disclosure also describes exemplary fabrication processes to manufacture certain embodiments of the present disclosure. In various examples, at least one fabrication process may include removing one or more passivation layers from one or more dicing lanes on an interconnection portion, bonding a device portion to the interconnection portion to form a bonded wafer, and exposing one or more permeable surfaces of the bonded wafer. In some examples, at least one fabrication process may further include depositing a first conformal alumina layer. The first conformal alumina layer may coat at least a portion of a bonded wafer. Additionally and/or alternatively, the first conformal alumina layer is configured to coat one or more exposed surfaces. The one or more exposed surfaces may be permeable to small gas molecules, non-permeable to small gas molecules, or a combination thereof.

Various methods and fabrication processes are disclosed for hermetically encapsulating one or more MEMS device to prevent permutation of small gas molecules, and exemplary embodiments of the methods and fabrication process will now be described with reference to the accompanying figures.

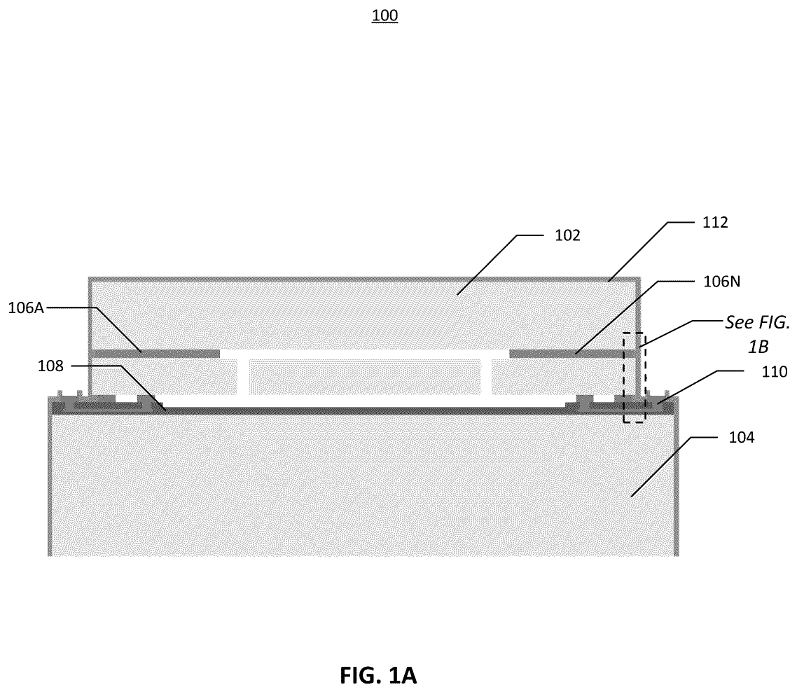

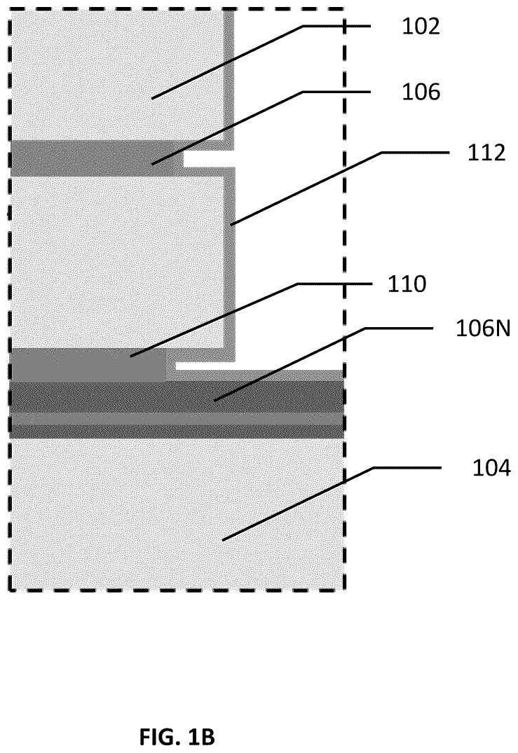

FIGS. 1A-1B illustrate schematic cross-section views of a MEMS device 100 according to various embodiments of the present disclosure. In one or more embodiments, the MEMS device may incorporate one or more mechanical structure having a dimensional scale that is comparable to microelectronic devices. For example, the MEMS device may be less than approximately 250 μm. In various embodiments, the MEMS device may be capable to perform at least one mechanical motion and may be formed at the micro-scale using fabrication techniques. In various embodiments, the MEMS device 100 may be an accelerometer, gyroscope, sensor, actuator, etc. In other embodiments, the MEMS device 100 may be a MEMS accelerometer that may be used in implantable pacemakers and/or defibrillators, such that the MEMS device 100 may detect mechano-acoustic signals of the heart and lungs. In one or more embodiments, one or more MEMS device 100 may comprise a device portion 102 (e.g., device wafer) and a base portion 104 (e.g., connection wafer). In various embodiments, the base portion 104 may be configured to at least partially house one or more electronic system of the MEMS device. The MEMS device may further comprise one or more interconnection portion 108 that may be disposed along a portion of the base portion 104. The one or more interconnection portion 108 can translate the entire length of the base portion. In some embodiments, the one or more interconnection portion 108 may translate only a portion of the length of the base portion 104. In various embodiments, the device portion 102 may be at least partially bonded (e.g., chemically, thermally, etc.) to the interconnection 108 and/or the base portion 104. In some embodiments, the device portion 102 may be configured to at least partially encapsulate a portion of the interconnection portion 108 and/or base portion (e.g., connection wafer).

With further reference to FIGS. 1A-1B, in various embodiments, at least a portion of the device portion 102 (e.g., device wafer), the interconnection portion 108, and/or the base portion 104 (e.g., connection wafer) may comprise one or more exposed surfaces. The one or more exposed surfaces may be permeable to small gas molecules (e.g., hydrogen, helium, etc.), non-permeable to small gas molecules (e.g., hydrogen, helium, etc.), and/or a combination thereof. In various embodiments, the one or more exposed surfaces that are permeable may be susceptible to ingression of small gas molecules, such that the MEMS device 100 may not be hermetically encapsulated, such that the ingression of small gas molecules may affect the operational stability, performance consistency, and robustness against environmental variations of the MEMS devices. As depicted in FIGS. 1A-1B, the MEMS device 100 may comprise one or more exposed permeable surfaces within the device portion 102 and/or a portion of the interconnection portion 108. The one or more exposed permeable surfaces may a silicon dioxide layer. The MEMS device may comprise at least a first silicon dioxide layer 106A and/or one or more additional silicon dioxide layer 106N. In various embodiments, at least a portion of the interconnection portion 108 may comprise a permeable surface/layer, such that at least a portion of the interconnection portion may comprise a silicon dioxide layer. As such, MEMS devices fabricated and packaged using substrates that include silicon-dioxide layers, such as a silicon-on-insulation (SOI) wafer (e.g., interconnection portion 108), may not be hermetic against helium, hydrogen, and/or any other small gas molecule ingression. In various embodiments, the first silicon dioxide layer 106A, the one or more additional silicon dioxide layer 106N, and/or at least a portion of the one or more interconnection portion 108 may be at least a portion of a buried oxide layer (BOX) of a SOI substrate of the MEMS device 100. Additionally and/or alternatively, the one or more exposed permeable surfaces may be the sidewalls of the first silicon dioxide layer 106A, the one or more additional silicon dioxide layer 106N, interconnection portion 108, and/or device portion 102. In various embodiments, the one or more exposed surfaces may be an undercut region of the device portion 102, the capping portion 104, and/or the interconnection portion 108. In various embodiments, the one or more exposed non-permeable surfaces 110 may be a portion of the interconnection portion 108 and/or the device portion 102. The one or more exposed non-permeable surfaces may be the sidewalls of the capping portion 104, interconnection portion 108, and/or device portion 102. Additionally and/or alternatively, the one or more exposed surfaces may be an undercut region of the device portion 102, the capping portion 104, and/or the interconnection portion 108.

With even further reference to FIGS. 1A-1B, in various embodiments, the MEMS device 100 further comprises at least one conformal alumina (Al₂O₃) layer 112 (e.g., first conformal alumina layer, second conformal alumina layer, and/or one or more additional conformal alumina layer). The at least one conformal alumina layer may be configured to at least partially coat a portion of one or more MEMS device 100 (e.g., one or more exposed surfaces, device portion, capping portion, interconnection portion, etc.). The at least one conformal alumina layer 112 may be deposited on to a portion of the MEMS device using and atomic layer deposition (ALD) method, such that the at least one conformal alumina layer 112 may hermetically encapsulates the MEMS device 100. The hermetic encapsulation of one or more MEMS device may be performed at either a chip-level or a wafer-level and may prevent helium and hydrogen leakage into the cavity of MEMS device 100. In various embodiments, the ALD of the at least one conformal alumina layer 112 may cause the at least one conformal alumina layer to conform and at least partially coat one or more exposed surfaces. In one or more embodiments, the at least one conformal alumina layer 112 may at least partially coat one or more exposed buried oxide layer (BOX) surfaces resulting from device releasing processes or dicing processes. Additionally and/or alternatively, the at least one conformal alumina layer 112 may at least partially coat one or more exposed passivation materials (e.g., first silicon dioxide layer 106A, one or more additional silicon dioxide layer 106N, and/or one or more interconnect/capping wafer 108) that are permeable to helium and hydrogen on an interconnection portion, capping portion, and/or device portion of one or more MEMS device 100. Additionally and/or alternatively, the at least one alumina layer 112 may at least partially coat one or more non-permeable surfaces (e.g., metal pads, electrical connection, etc.). The at least one conformal alumina layer 112 that at least partially coat one or more non-permeable surfaces may be removed by one or more of the following processes: etching, blanket etching, reactive-ion etching, focused ion beam etching, laser trimming, or a combination thereof.

In various embodiments, the MEMS device 100 may comprise a first conformal alumina layer 112 deposited on a first portion of the MEMS device 100 and/or one or more additional conformal alumina layer (not depicted) deposition on one or more additional portion of the MEMS device 100. The first conformal alumina layer 112 may be deposited on a top surface of the device portion 102, such that the first conformal alumina layer may at least partially coat a portion of the device portion 102 and/or one or more exposed surfaces of the device portion 102 and/or the interconnection portion 108. The one or more additional conformal alumina layer (e.g., second conformal alumina layer) may be deposited along a bottom surface of the capping portion of the MEMS device, such that the one or more additional conformal alumina layer may at least partially coat a portion of the capping portion 104 and/or one or more exposed surfaces of the device portion 102 and/or the interconnection portion 108. In one or more embodiments, the one or more additional conformal alumina layer may be deposited at a location on the MEMS device, such that at least a portion of the one or more additional conformal alumina layer at least partially overlaps with a portion of the first conformal alumina layer. The overlap of a portion of the one or more additional conformal alumina layer with a portion of the first conformal alumina layer may be configured to achieve a predetermined desired thickness for hermetic encapsulation. In some embodiments, a third conformal alumina layer may be deposited directly on top of the first conformal alumina layer and/or the one or more additional conformal alumina layer (e.g., second conformal alumina layer), such that a predetermined thickness of the conformal alumina layer is achieved to ensure hermetic encapsulation of the MEMS device 100.

In various embodiments, the thickness of the first conformal alumina layer and/or the one or more additional conformal alumina layer may be a predetermined thickness, such that the thickness achieves hermetic encapsulation of the MEMS device 100. In one or more embodiments, the thickness of the first conformal alumina layer and/or the one or more additional conformal alumina layer may be at least 10 nm. In other embodiments, the thickness of the first conformal alumina layer and/or the one or more additional conformal alumina layer may be up to 200 nm. In another embodiment, the thickness of the first conformal alumina layer and/or the one or more additional conformal alumina layer may be 100 nm.

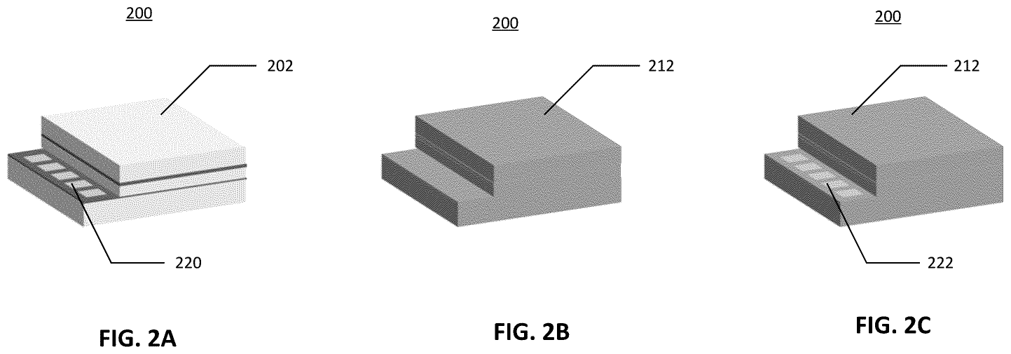

FIGS. 2A-2C illustrate at least one conformal alumina layer coating a portion of a MEMS device according to various embodiments of the present disclosure. FIG. 2A illustrates an example MEMS device 200 without one or more conformal alumina layer deposited on a singulated capped MEMS chip 202. The MEMS device 200 may comprise one or more exposed surfaces 220. The one or more exposed surfaces may be permeable surfaces and/or non-permeable surfaces of a device portion, capping portion, and/or interconnection portion of the MEMS device. Additionally and/or alternatively, the one or more exposed surfaces may be one or more electrical connection pads of the interconnection portion. FIG. 2B illustrates a first deposited layer configured to at least partially coat one or more exposed surfaces 220 and/or at least partially coat a portion of the device portion, capping portion, and/or interconnection portion. In various embodiments, the MEMS device 200 may be flipped up-side-down, such that one or more additional conformal alumina layer may be deposited on a portion of the MEMS device to at least partially coat a bottom portion of the MEMS device 200. FIG. 2C illustrates removal of at least a portion of the first conformal alumina layer and/or the one or more additional conformal alumina layer to expose one or more non-permeable surfaces of the MEMS device. One or more etching processes may be used to remove at least a portion of the first conformal alumina layer and/or the one or more additional conformal alumina layer to access the one or more non-permeable surfaces 222 (e.g., electrical connection pads, electrical access to the MEMS device, circuitry, etc.).

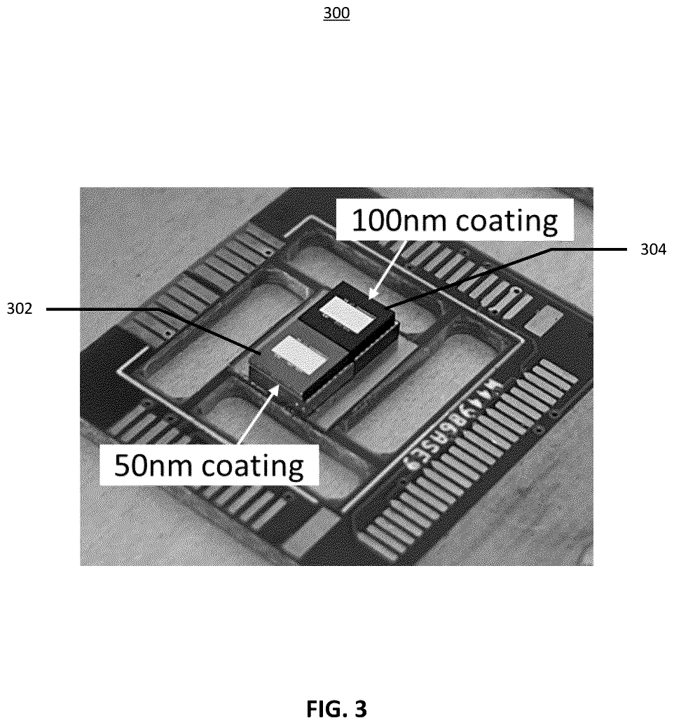

FIG. 3 illustrates exemplary MEMS devices according to various embodiments of the present disclosure. As depicted in FIG. 3, one or more MEMS devices 300 may be configured for chip-level ALD conformal alumina coating with one or more thicknesses and selective etching for revealing one or more non-permeable surfaces. A first MEMS device 302 and one or more additional MEMS device 304 may comprise different conformal alumina layer thicknesses. In various embodiments, the first MEMS device 302 may comprise a conformal alumina layer thickness of 50 nm and/or the one or more additional MEMS device 304 may comprise a conformal alumina layer thickness of 100 nm. In various embodiments, the first MEMS device 302 and the one or more additional MEMS device 304 may comprise an equal conformal alumina layer thickness. In various embodiments, the first MEMS device 302 may comprise a conformal alumina layer thickness configured to hermetically encapsulate the first MEMS device 302 and/or the one or more additional MEMS device 304 may comprise a conformal alumina layer thickness configured to hermetically encapsulate the one or more additional MEMS device 304.

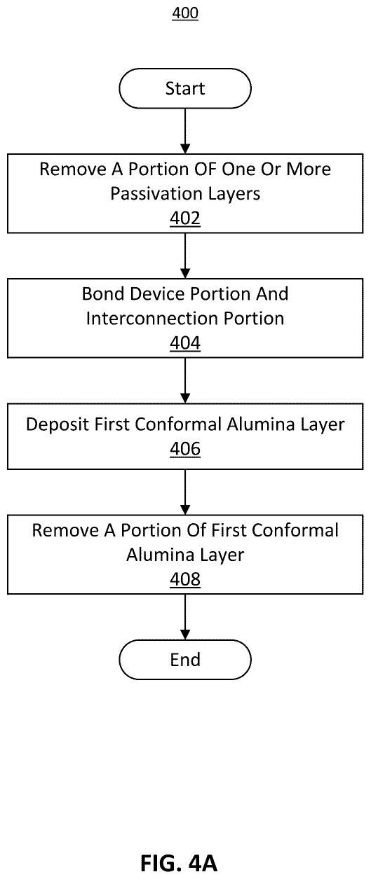

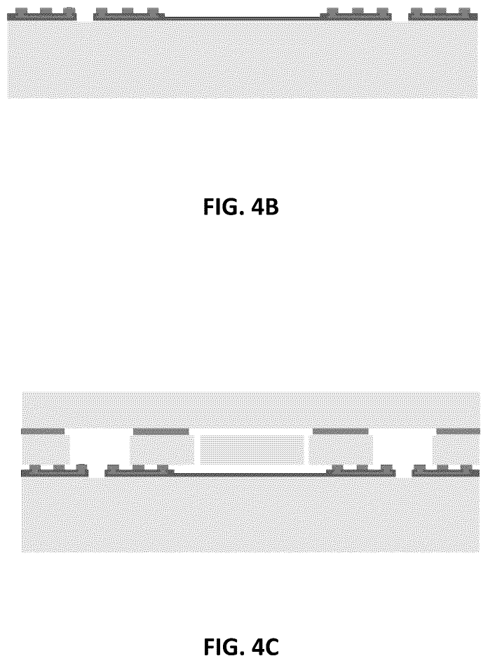

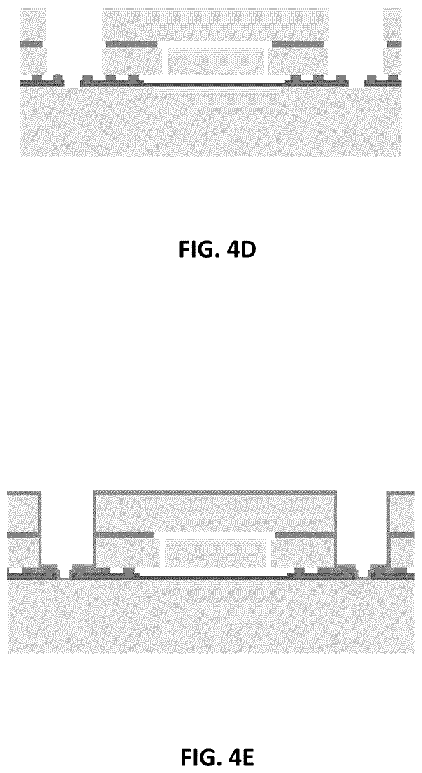

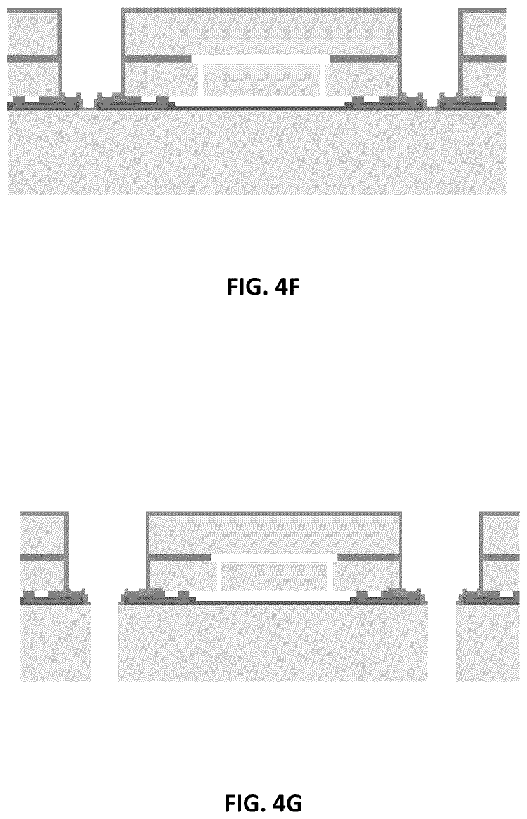

FIG. 4A illustrates an exemplary flow diagram for wafer-level implementation of an exemplary method and fabrication process 400 for hermetic encapsulation of a micro-electromechanical system (MEMS). The steps of the exemplary method and fabrication process 400 may reference FIGS. 4B-4G to illustrate the fabrication process of the one or more MEMS devices. Additionally, the steps of the exemplary method and fabrication process 400 may reference components and the components functions, as described in more detail with respect to FIGS. 1A-3.

An exemplary method and fabrication process 400 for wafer-level implementation of hermetic encapsulation of one or more MEMS device may begin with at least one interconnection portion disposed on at least a portion of the capping portion. The at least one interconnection portion may undergo a selective etching operation to remove at least a portion of one or more passivation layers, see block 402. Depicted in FIG. 4B. In various embodiments, the selective etching process may be configured to assist with the removal of the one or more passivation layer of the one or more interconnection portion and/or capping portion, such that one or more exposed surfaces are revealed. The one or more exposed surfaces may be a permeable surface and/or a non-permeable surface. In various embodiments, the one or more exposed permeable surfaces may be the exterior surface(s) of a chip cavity. In an instance in which the one or more interconnection portion and/or the capping portion comprises helium and/or hydrogen permeable passivation layers, such as SiO₂ being used as an interconnection portion configured to bond with the device portion, the one or more passivation layers may be etched into patterns and removed from one or more dicing lanes to ensure ALD conformal alumina coverage of the sidewall of the passivation layers. In one or more embodiments, the interconnection portion may be a CMOS wafer, such that the CMOS wafer contains one or more interface circuitry for the one or more MEMS devices.

At block 404, the one or more interconnection/capping wafer is configured to bonded to the device wafer via any necessary bonding techniques. Depicted in FIGS. 4C-4D. In various embodiments, after wafer bonding of the interconnection/capping wafer and the device wafer containing the MEMS, the MEMS may be configured to go through any other necessary processing steps (wafer grinding, scribing, etc.) and/or the bonded wafer may go through one or more additional partial dicing to expose one or more permeable surfaces, such as one or more sidewall of at least one BOX layer of an SOI wafer. In various embodiments, the one or more exposed surfaces may be at least one sidewall of the interconnection portion, capping portion and/or, device portion, as illustrated in FIG. 1A. Additionally and/or alternatively, the one or more exposed surfaces may be at least one undercut region of the interconnection portion, device portion, and/or the bonding of the interconnection portion with the device portion.

At block 406, a first conformal alumina layer may be deposited on at least a portion of the MEMS device, such that the first conformal alumina layer coats one or more exposed permeable surfaces and/or one or more exposed non-permeable surfaces. Depicted in FIG. 4E. In various embodiments, the first conformal alumina layer may coat one or more exposed permeable surfaces, such that the one or more permeable surfaces may be at least one sidewall of the interconnection portion, capping portion, and/or device portion. The first conformal alumina layer may be further configured to at least partially coat one or more exposed surfaces of undercut regions of an interconnection portion, device portion, and/or the bonding of the interconnection portion with the device portion. Additionally and/or alternatively, the first alumina layer may further coat the one or more non-permeable surface, such as one or more electrical connection pads of the MEMS device.

At block 408, at least a portion of the first deposited conformal alumina layer may be removed from a portion of the MEMS device, such that the one or more non-permeable surfaces (e.g., electrical connection pads) are exposed. Depicted in FIG. 4F. The portion of the deposited first conformal alumina layer being removed may be removed via one or more selective removal processes, such as reactive ion etching using a shadow mask, etching, blanket etching, reactive-ion etching, focused ion beam etching, laser trimming, or a combination thereof. In various embodiments, the MEMS device may additionally undergo one or more additional dicing processes using common wafer dicing techniques for chip singulation. Depicted in FIG. 4G. In various embodiments, the method and fabrication described above may be applied to two or more MEMS devices simultaneously and/or individually.

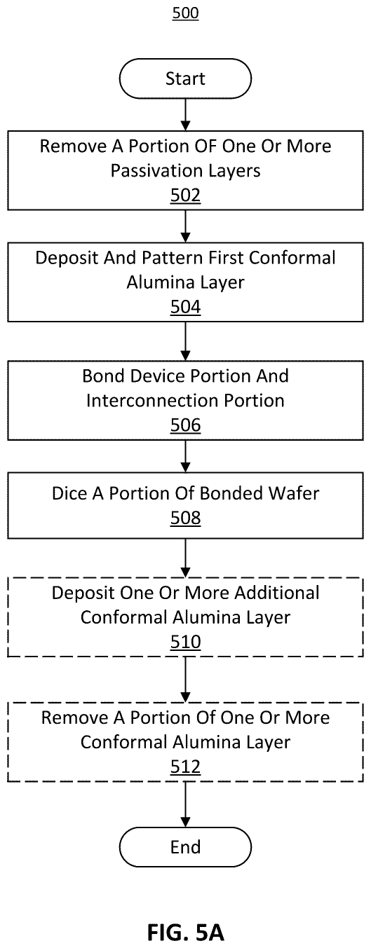

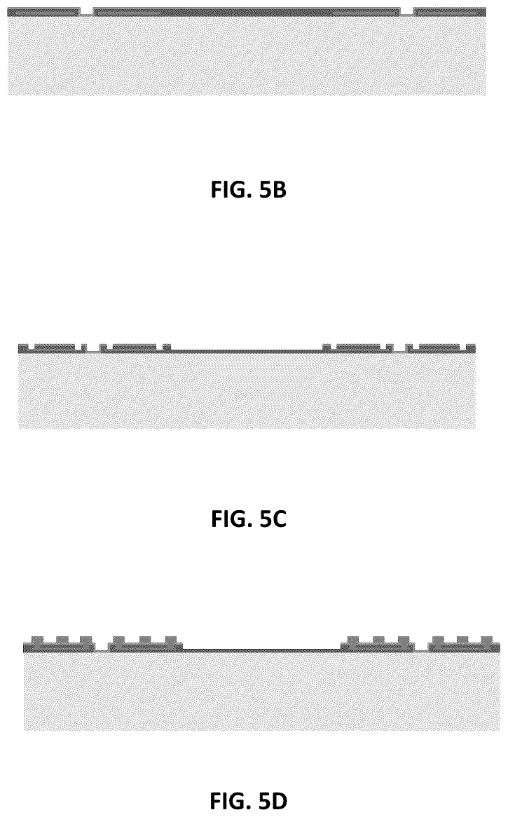

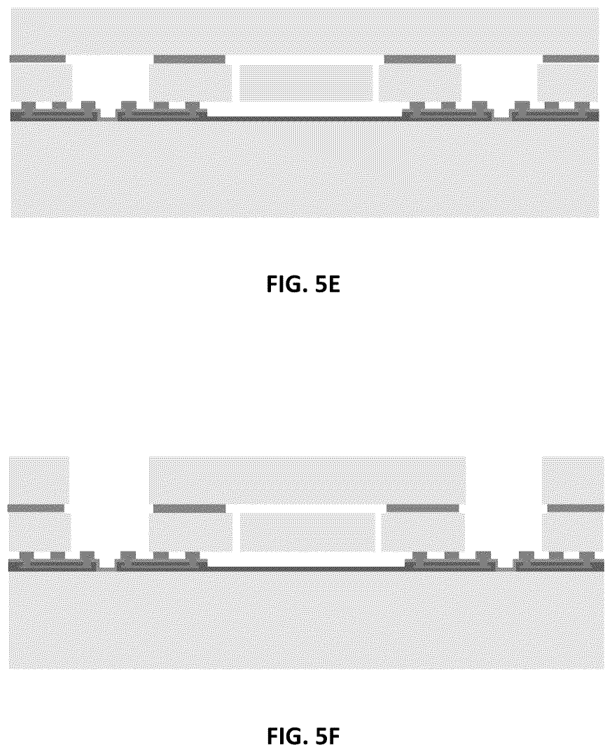

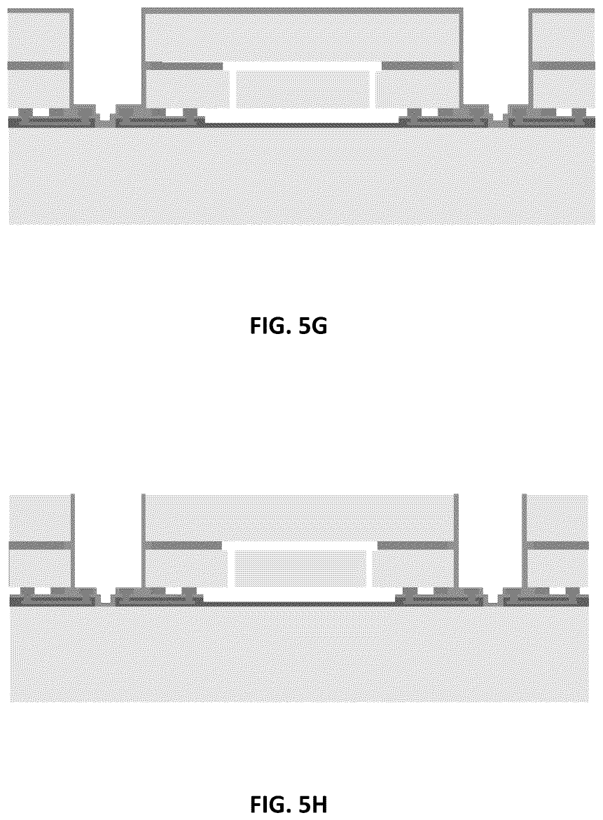

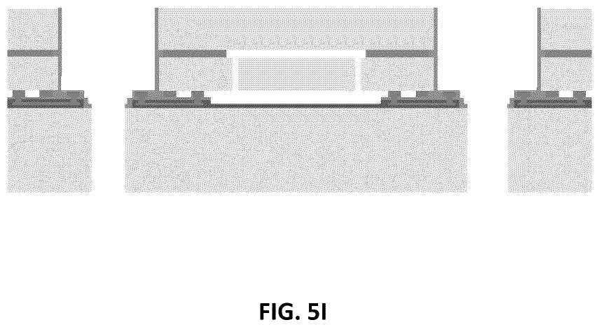

FIG. 5A illustrates a flow diagram for wafer-level implementation of an exemplary method and fabrication process 500 for hermetic encapsulation of a micro-electromechanical system (MEMS). The steps of the exemplary method and fabrication process 500 may reference FIGS. 5B-5I to illustrate the fabrication process for hermetically encapsulating one or more MEMS devices. The steps of the fabrication process 500 may reference components and the components functions, as described in more detail with respect to FIGS. 1A-3.

An exemplary method and fabrication process 500 for wafer-level implementation of hermetic encapsulation of one or more MEMS device may begin with one or more interconnection portion disposed on a capping portion. The at least one interconnection portion may undergo a selective etching operation to remove at least a portion of one or more passivation layers, see block 502. Depicted in FIG. 5B. In various embodiments, the selective etching process may be configured to assist with the removal of the one or more passivation layer of the one or more interconnection portion and/or capping portion, such that one or more exposed surfaces are revealed. The one or more exposed surfaces may be a permeable surface and/or a non-permeable surface. In various embodiments, the one or more exposed permeable surfaces may be the exterior surface(s) of a chip cavity. In an instance in which the one or more interconnection portion and/or the capping portion comprises helium and/or hydrogen permeable passivation layers, such as SiO₂ being used as an interconnection portion configured to bond with the device portion, the one or more passivation layers may be diced into patterns and removed from one or more dicing lanes to ensure ALD conformal alumina coverage of the sidewall of the passivation layers. In one or more embodiments, the interconnection portion may be a CMOS wafer, such that the CMOS wafer contains one or more interface circuitry for the one or more MEMS devices.

At block 504, a first conformal alumina layer may be deposited on at least a portion of the MEMS device, such that the first conformal alumina layer may coat one or more exposed surfaces (e.g., one or more exposed permeable surfaces, one or more exposed non-permeable surfaces, or a combination thereof) of an interconnection portion and/or a capping portion. Depicted in FIG. 5B. In various embodiments, the first conformal alumina layer may coat one or more exposed permeable surfaces. The one or more permeable surfaces may be at least one sidewall of the interconnection portion and/or capping portion. The first conformal alumina layer may be further configured to at least partially coat one or more exposed surfaces of undercut regions of an interconnection portion. Additionally and/or alternatively, the first alumina layer may further coat one or more non-permeable surface, such as one or more electrical connection pads of the MEMS device. In one or more embodiments, one or more additional processes may be performed on at least a portion the interconnection portion after the first conformal alumina layer is deposited. In one or more embodiments, at least a portion of the first deposited conformal alumina layer may be removed from the interconnection portion and/or capping portion. The removal of at least a portion of the first deposited conformal alumina layer may be configured to expose one or more electrical connection pads and/or one or more additional non-permeable surfaces. Depicted in FIG. 5C. The portion of the deposited first conformal alumina layer may be removed via one or more selective removal processes, such as reactive ion etching using a shadow mask, etching, blanket etching, reactive-ion etching, focused ion beam etching, laser trimming, or a combination thereof. In various embodiments, the interconnection portion may undergo one or more additional process, such as electroplating, for bond metal formation. Depicted in FIG. 5D.

At block 506, the one or more interconnection portion may be configured to bonded to the device portion via any necessary bonding techniques. Depicted in FIG. 5E. In various embodiments, after bonding the interconnection portion and the device portion containing one or more electrical component for the MEMS device, the MEMS device may undergo one or more additional necessary processing steps (wafer grinding, scribing, etc.).

At block 508, the bonded wafer (e.g., the interconnection portion and capping portion bonded with the device portion) may undergo one or more additional partial dicing to expose one or more permeable surfaces and/or one or more non-permeable surfaces. Depicted in FIG. 5F. The one or more permeable surfaces may be at least one sidewall of the interconnection portion, device portion, and/or capping portion. Additionally and/or alternatively, the one or more exposed permeable surfaces may be undercut regions of an interconnection portion, device portion, and/or the connection between the interconnection portion and/or device portion and/or the one or more exposed permeable surfaces may be the sidewalls of a BOX layer of an SOI wafer. In one or more embodiments, the one or more non-permeable surface may be a portion of the capping portion, interconnection portion, and/or device portion. For example, the one or more electrical connection pads on the interconnection portion of the MEMS device.

At block 510, one or more additional conformal alumina layer may be deposited on at least a portion of the MEMS device, such that the one or more additional conformal alumina layer (e.g., second conformal alumina layer, third conformal alumina layer, etc.) may at least partially coat the one or more exposed permeable surfaces and/or the one or more exposed non-permeable surfaces of the interconnection portion, capping portion, and/or the device portion. Depicted in FIG. 5G. In various embodiments, the one or more additional conformal alumina layer may coat one or more exposed permeable surfaces of the sidewalls of the interconnection portion, capping portion, and/or the device portion. The one or more additional conformal alumina layer may further coat at least a portion of the one or more exposed permeable surfaces of the undercut regions of the interconnection portion, device portion, and/or the connection between the device portion and the interconnection portion. In various embodiments, the one or more additional conformal alumina layer may at least partially coat one or more exposed non-permeable surfaces of the sidewalls of the interconnection portion, capping and/or the device portion. The one or more additional conformal alumina layer may be further configured to at least partially coat the one or more exposed non-permeable surfaces of the undercut regions of the interconnection portion, device portion, and/or the connection between the device portion and the interconnection portion. Additionally and/or alternatively, the one or more additional alumina layer may at least partially coat one or more electrical connection pads of the MEMS device.

At block 512, at least a portion of the first deposited conformal alumina layer and/or the one or more additional deposited conformal alumina layers may be removed from the interconnection portion, capping portion, and/or the device portion of one or more MEMS device. The removal of at least a portion of the first deposited conformal alumina layer and/or the one or more additional deposited conformal layer may be configured to expose one or more electrical connection pads and/or one or more additional non-permeable surfaces. Depicted in FIG. 5H. The portion of the deposited first conformal alumina layer and/or one or more additional deposited conformal alumina layer may be removed via one or more removal processes, such as reactive ion etching using a shadow mask, blanket etching, etching, reactive-ion etching, focused ion beam etching, laser trimming, or a combination thereof. In various embodiments, the MEMS device may additionally undergo one or more additional dicing processes using common wafer dicing techniques for chip singulation. Depicted in FIG. 5I.

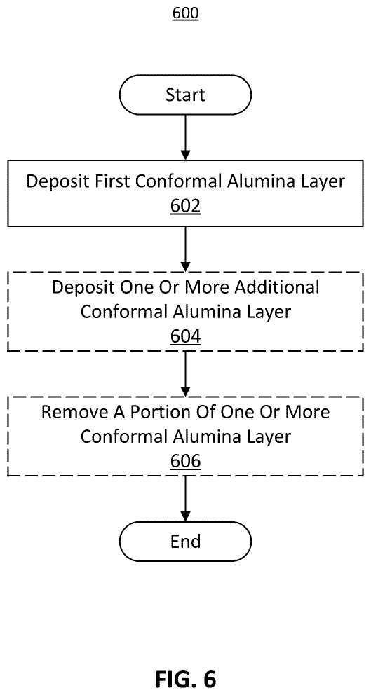

FIG. 6 illustrates an exemplary flow diagram for chip-level implementation of an exemplary method and fabrication process 600 for hermetic encapsulation of a micro-electromechanical system (MEMS). The steps of the exemplary method and fabrication process 600 may reference components and the components functions, as described in more detail with respect to FIGS. 1A-3.

An exemplary method and fabrication process 600 for chip-level implementation of hermetic encapsulation of one or more MEMS device may begin one or more MEMS chips with one or more exposed surfaces that may be a permeable surface and/or a non-permeable surface. In various embodiments, the one or more exposed permeable surfaces may be the exterior surface(s) of a chip cavity. In an instance in which the one or more interconnection portion, capping portion, and/or device portion comprises helium and/or hydrogen passivation layers, such as SiO₂ being used as an interconnection portion configured to bond with the device portion, the one or more passivation layers may be diced into patterns and removed from one or more dicing lanes to ensure ALD conformal alumina coverage of the sidewall of the passivation layers. In one or more embodiments, the interconnection portion may be a CMOS wafer, such that the CMOS wafer contains one or more interface circuitry for the one or more MEMS devices. At block 602, a first conformal alumina layer may be deposited on at least a portion of the MEMS device, such that the first conformal alumina layer may at least partially coat the interconnection portion, capping portion, device portion, one or more exposed permeable surfaces, and/or one or more exposed non-permeable surfaces. In various embodiments, the first conformal alumina layer may coat one or more exposed permeable surfaces, such that the one or more permeable surfaces may be at least one sidewall of the interconnection portion, capping portion, and/or device portion. The first conformal alumina layer may be further configured to at least partially coat one or more exposed surfaces of undercut regions of an interconnection portion, device portion, and/or the bonding of the interconnection portion with the device portion. Additionally and/or alternatively, the first alumina layer may further coat the one or more non-permeable surface, such as one or more electrical connection pads of the MEMS device.

At block 604, one or more additional conformal alumina layer may be deposited on at least a portion of the MEMS device, such that the one or more additional conformal alumina layer (e.g., second conformal alumina layer, third conformal alumina layer, etc.) may at least partially coat the one or more exposed permeable surfaces and/or the one or more exposed non-permeable surfaces of the interconnection portion, capping portion, and/or the device portion. In one or more embodiments, the one or more MEMS device may be flipped up-side-down to deposit the one or more additional conformal alumina layer on the bottom of the MEMS chip. In various embodiments, the one or more additional conformal alumina layer may at least partially coat one or more exposed permeable surfaces of the sidewalls of the interconnection portion, capping portion, and/or the device portion. The one or more additional conformal alumina layer may be further configured to coat at least a portion of the one or more exposed permeable surfaces of the undercut regions of the interconnection portion, device portion, and/or the connection between the device portion and the interconnection portion. In various embodiments, the one or more additional conformal alumina layer may at least partially coat one or more exposed non-permeable surfaces of the sidewalls of the interconnection portion, capping and/or the device portion. The one or more additional conformal alumina layer may be further configured to at least partially coat the one or more exposed non-permeable surfaces of the undercut regions of the interconnection portion, device portion, and/or the connection between the device portion and the interconnection portion.

At block 606, at least a portion of the first deposited conformal alumina layer and/or the one or more additional deposited conformal alumina layers may be removed from a portion of the interconnection portion, capping portion, and/or the device portion of one or more MEMS device. The removal of at least a portion of the first deposited conformal alumina layer and/or the one or more additional deposited conformal layer may be configured to expose one or more electrical connection pads and/or one or more additional non-permeable surfaces. The portion of the deposited first conformal alumina layer and/or one or more additional deposited conformal alumina layer may be removed via one or more selective removal processes, such as reactive ion etching using a shadow mask, blanket etching, etching, reactive-ion etching, focused ion beam etching, laser trimming, or a combination thereof. In various embodiments, the MEMS device may additionally undergo one or more additional dicing processes using common wafer dicing techniques for chip singulation.

Certain embodiments and implementations of the disclosed technology are described above with reference to block and flow diagrams of fabrication processes and methods according to example embodiments or implementations of the disclosed technology. It will be understood that some blocks of the block diagrams and flow diagrams may not necessarily need to be performed in the order presented, may be repeated, or may not necessarily need to be performed at all, according to some embodiments or implementations of the disclosed technology.

It is to be understood that the embodiments and claims disclosed herein are not limited in their application to the details of construction and arrangement of the components set forth in the description and illustrated in the drawings. Rather, the description and the drawings provide examples of the embodiments envisioned. The embodiments and claims disclosed herein are further capable of other embodiments and of being practiced and carried out in various ways. Also, it is to be understood that the phraseology and terminology employed herein are for the purposes of description and should not be regarded as limiting the claims.

Accordingly, those skilled in the art will appreciate that the conception upon which the application and claims are based may be readily utilized as a basis for the design of other structures, methods, and systems for carrying out the several purposes of the embodiments and claims presented in this application. It is important, therefore, that the claims be regarded as including such equivalent constructions.

Furthermore, the purpose of the foregoing Abstract is to enable the United States Patent and Trademark Office and the public generally, and especially including the practitioners in the art who are not familiar with patent and legal terms or phraseology, to determine quickly from a cursory inspection the nature and essence of the technical disclosure of the application. The Abstract is neither intended to define the claims of the application, nor is it intended to be limiting to the scope of the claims in any way. Instead, it is intended that the invention is defined by the claims appended hereto.

What is claimed is:

1. A method for hermetic encapsulation of a micro-electromechanical system (MEMS) device, the method comprising:
depositing a first conformal alumina layer to coat at least a portion of the MEMS device, wherein the first conformal alumina layer is configured to coat one or more exposed surfaces of the MEMS device; and
removing at least a portion of a deposited first conformal alumina layer from one or more impermeable surfaces of the MEMS device.

2. The method of claim 1, wherein depositing the first conformal alumina layer and one or more additional conformal layers utilizes an atomic layer deposition (ALD) method.

3. The method of claim 1, wherein the one or more exposed surfaces at least partially coated by a respective conformal alumina layer are configured to be permeable to hydrogen, helium, or a combination thereof.

4. The method of claim 3, wherein the first conformal alumina layer is configured to coat one or more exposed surfaces of an undercut region of an interconnection portion, a capping portion, a device portion, or a combination thereof.

5. The method of claim 1, the method further comprising:
depositing one or more additional conformal alumina layers to coat at least a portion of one or more exposed surfaces disposed along a bottom portion of the MEMS device, wherein the one or more exposed surfaces are configured to be permeable to hydrogen, helium, or a combination thereof.

6. The method of claim 5, wherein the one or more additional conformal alumina layer is configured to coat one or more exposed surfaces of an undercut region of an interconnection portion, a capping portion, a device portion, or a combination thereof.

7. The method of claim 5, wherein removing at least a portion of the first deposited conformal alumina layer from the one or more impermeable surfaces utilizes one or more of the following processes: blanket etching, reactive-ion etching, focused ion beam etching, laser trimming, or a combination thereof.

8. A method for hermetic encapsulation of a micro-electromechanical system (MEMS) device, the method comprising:
removing one or more passivation surfaces of an interconnection portion of the MEMS device along at least one dicing lane, wherein the one or more passivation surfaces are permeable;
bonding the interconnection portion to a device portion to form the bonded wafer, wherein the device portion contains one or more electrical component for the MEMS device;
dicing at least a portion of a bonded wafer; and
depositing a first conformal alumina layer to coat at least a portion of the bonded wafer, wherein the first conformal alumina layer coats at least a portion of one or more exposed surfaces.

9. The method of claim 8, the method further comprising:
removing at least a portion of the deposited first conformal alumina layer layers from one or more impermeable surfaces of the MEMS device.

10. The method of claim 8, wherein depositing the first conformal alumina layer utilizes an atomic layer deposition (ALD) method.

11. The method of claim 8, wherein one or more exposed surfaces coated by a respective conformal alumina layer are configured to be permeable to hydrogen, helium, or a combination thereof.

12. The method of claim 8, wherein the first conformal alumina layer coats one or more exposed surfaces of an undercut region of an interconnection portion, a capping portion, a device portion, or a combination thereof.

13. The method of claim 8, wherein removing of at least a portion of the first deposited conformal alumina layer from the one or more impermeable is done by one or more of the following processes: blanket etching, reactive-ion etching, focused ion beam etching, laser trimming, or a combination thereof.

14. A micro-electromechanical system (MEMS) device fabrication process for hermetic encapsulation, the process comprising:
removing one or more passivation layers from one or more dicing lanes on an interconnection portion and/or a device portion of a MEMS device, wherein the removing of the one or more passivation layer exposes one or more surfaces of the MEMS device;
depositing a first conformal alumina layer to coat at least a portion of the interconnection portion and/or device portion, wherein the first conformal alumina layer coats at least a portion of the one or more exposed surfaces; and
removing at least a portion of the first conformal alumina layer from one or more impermeable surfaces of the interconnection portion.

15. The fabrication process of claim 14, wherein the fabrication process further comprising:
bonding the interconnection portion to the device portion to form the bonded wafer, wherein the device portion is configured to contain one or more electrical and/or mechanical component for the MEMS device.

16. The fabrication process of claim 15, wherein the fabrication process further comprising:
depositing one or more additional conformal alumina layer to coat at least a portion of the bonded wafer, wherein the one or more additional conformal alumina layer coats at least a portion of one or more exposed surfaces.

17. The fabrication process of claim 16, wherein the fabrication process further comprising:
removing at least a portion of the deposited first conformal alumina layer and/or the deposited one or more additional conformal alumina layers from one or more impermeable surfaces of the bonded wafer.

18. The fabrication process of claim 16, wherein one or more exposed surfaces coated by a respective conformal alumina layer are permeable to hydrogen, helium, or a combination thereof.

19. The fabrication of claim 16, wherein the first conformal alumina layer and the one or more additional conformal layer coat one or more exposed surfaces of an undercut region of an interconnection portion, a capping portion, a device portion, or a combination thereof.

20. The fabrication of claim 19, wherein removing at least a portion of the first deposited conformal alumina layer and/or the one or more additional deposited conformal alumina layer from the one or more impermeable surfaces utilizes one or more of the following processes: blanket etching, reactive-ion etching, focused ion beam etching, laser trimming, or a combination thereof.
